(19) United States
(12) Patent Application Publication
(10) Pub. No.: US 2005/0130066 A1
(43) Pub. Date: Jun. 16, 2005

(54) Method of forming single sided conductor and semiconductor device having the same

(76) Inventors: Chin-Te Kuo, Taipei (TW); Jeng Ping Lin, Taoyuan (TW); Shian-Jyh Lin, Taipei (TW); Tsan Lu, Taipei (TW)

Correspondence Address: BIRCH STEWART KOLASCH & BIRCH, PO BOX 747, FALLS CHURCH, VA, 22040-0747, US

(21) Appl. No.: 10/731,133

(22) Filed: Dec. 10, 2003

(51) Int. Cl. G03F 7/00

(52) U.S. Cl. 430/311; 430/313; 430/315

(57) ABSTRACT

A method of forming a single sided conductor and a semiconductor device having the same is provided. The method includes providing a substrate having an opening. The opening exposes a sidewall and an opening base surface. A tilted mask layer is formed in the opening. The tilted mask layer exposes the sidewall and a portion of the opening base surface. A dielectric layer is formed on the exposed sidewall and the exposed opening base surface. Then, the tilted mask layer is removed, and a conductive layer is formed over the substrate.

### FIELD OF INVENTION

The present invention generally relates to a method of forming a semiconductor device, and more particularly, to a method of forming a single sided conductor of a semiconductor device by using a tilted mask layer.

### BACKGROUND OF THE INVENTION

The formation of semiconductor devices often requires processing on one side of a trench. For example, this may involve an isolation structure of dielectric layer or a conductive structure on one side of the trench, whereas the other side of the trench remains unchanged. However, as the feature size of the semiconductor device shrinks, the use of lithography technique to define the single sided conductor becomes difficult to control, or even fails to comply with the need of practical applications. Therefore, to form a sub-lithographic single sided conductor without using any extra lithography process is an advance development.

A conventional single sided conductor is generally formed by filling the trench with a polysilicon layer. Then, a nitride liner and an amorphous silicon layer are deposited thereon. By controlling the angle of implantation, a portion of the amorphous silicon layer along one side of the trench remains unimplanted. Then, the implanted amorphous silicon layer is removed and the nitride liner thereunder is exposed. The exposed nitride liner and the polysilicon layer thereunder are etched by using the unimplanted amorphous silicon layer as a mask to expose one side of the trench for subsequent processes, and the other side of the trench is protected by the unimplanted amorphous silicon layer. However, the etching process is difficult to control so that the residual amorphous silicon layer and the nitride liner might be thinner or even eliminated making the polysilicon etched profile become poor and reducing the reliability of devices and the production yield.

Therefore, it is desire to provide a method of forming a single sided conductor with excellent profile and without using extra lithography processes.

### SUMMARY OF THE INVENTION

One aspect of the present invention is to provide a method of forming a single sided conductor, which can be a sub-lithographic feature without implementing extra lithography processes.

Another aspect of the present invention is to provide a method of forming a single sided conductor by using a tilted mask layer as a mask to form a selective deposited oxide layer on the sidewall of an opening where the single sided conductor is to be formed.

A further aspect of the present invention is to provide a method of forming a semiconductor device having a single sided conductor, such as a trench capacitor, which controls the feature size of the single sided conductor by adjusting the tilt angle of the substrate and the thickness of a photoresist layer.

In one embodiment, a method of forming a single sided conductor includes providing a substrate having an opening. The opening exposes a sidewall and an opening base surface. A tilted mask layer is formed in the opening exposing the sidewall and a portion of the opening base surface. A dielectric layer, such as liquid phase deposition formed oxide layer, is formed on the exposed sidewall and the exposed opening base surface. To accomplish the formation of the single sided conductor, the tilted mask layer is then stripped, and a conductive layer is formed.

The step of forming the tilted mask layer includes coating a layer of photoresist over the substrate. It is noted that a portion of the photoresist is removed so that the opening is partially filled with the photoresist layer. Then, the substrate is tilted and the photoresist layer is reflowed to form the tilted mask layer in the opening. Furthermore, the substrate is preferably heated to a temperature about 100 to 150° C. for about 100 to 150 seconds during the reflow of the photoresist layer. After the photoresist layer is reflowed, the tilted mask layer is hardened by ultraviolet. Moreover, before the dielectric layer is formed, a native oxide is formed on the exposed sidewall and the exposed opening base surface.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1D illustrate cross-sectional views of forming a single sided conductor in a first embodiment of the present invention; and

FIGS. 2A to 2F illustrate cross-sectional views of forming a semiconductor device having a single sided conductor in a second embodiment of the present invention.

### DETAILED DESCRIPTION OF THE INVENTION

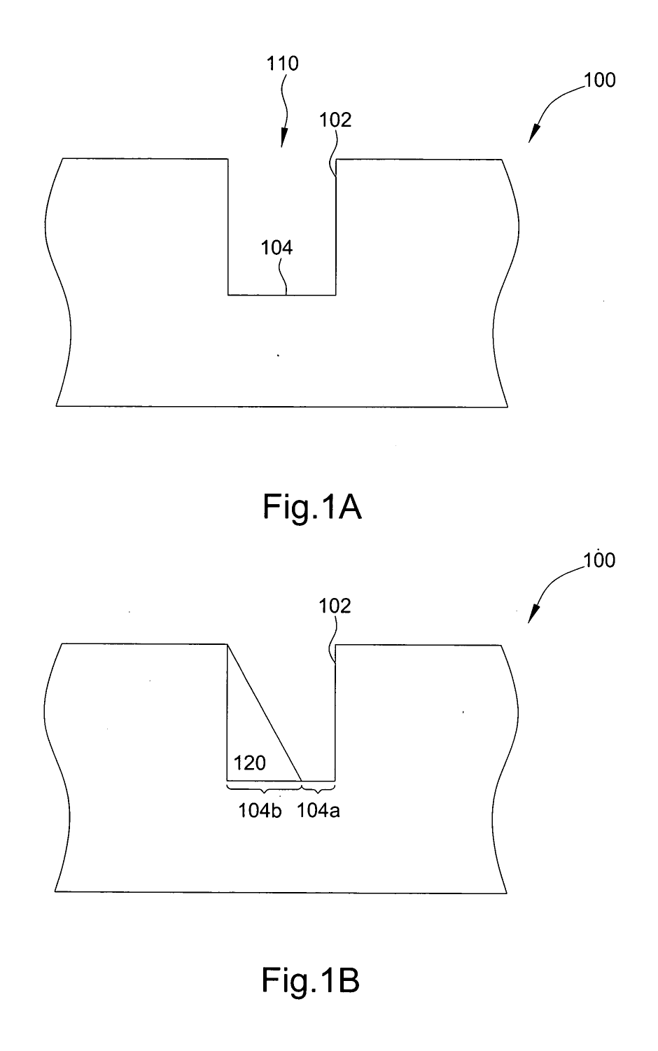

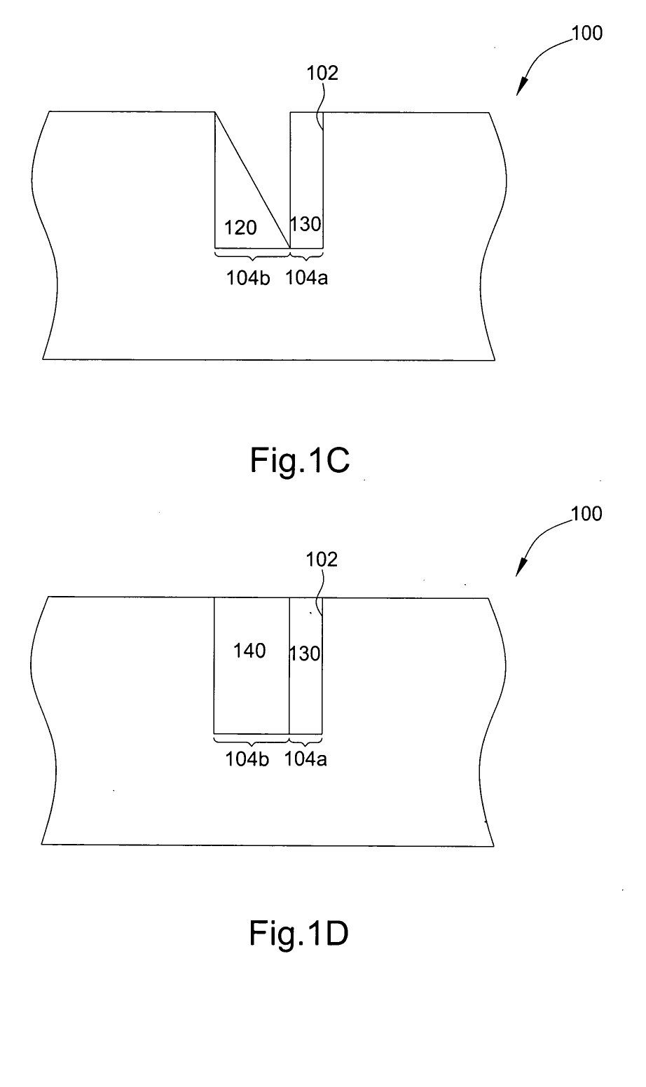

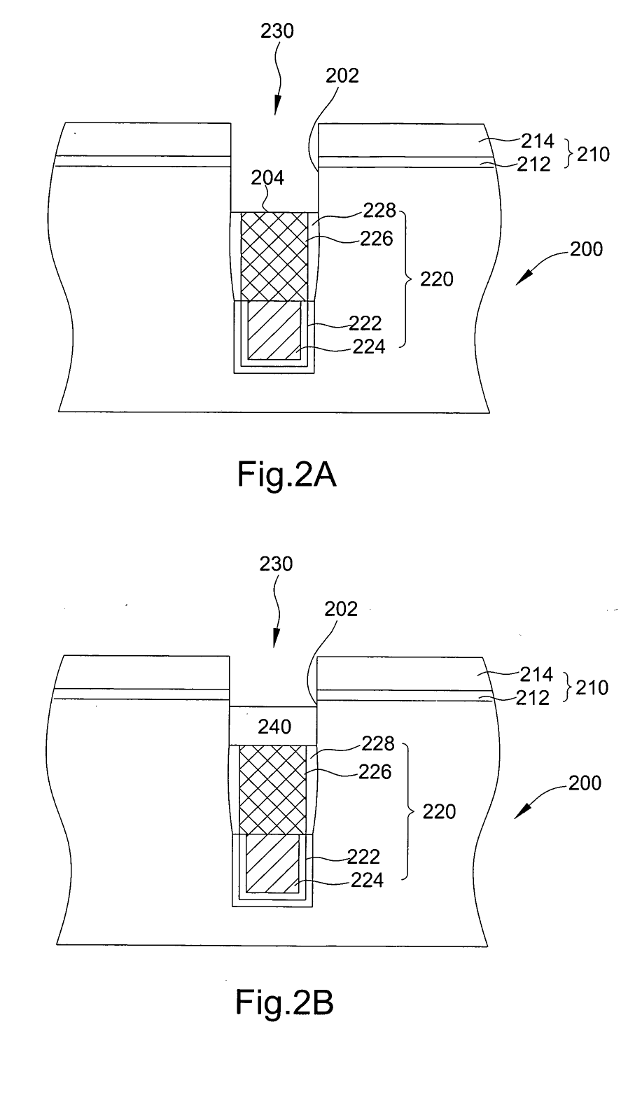

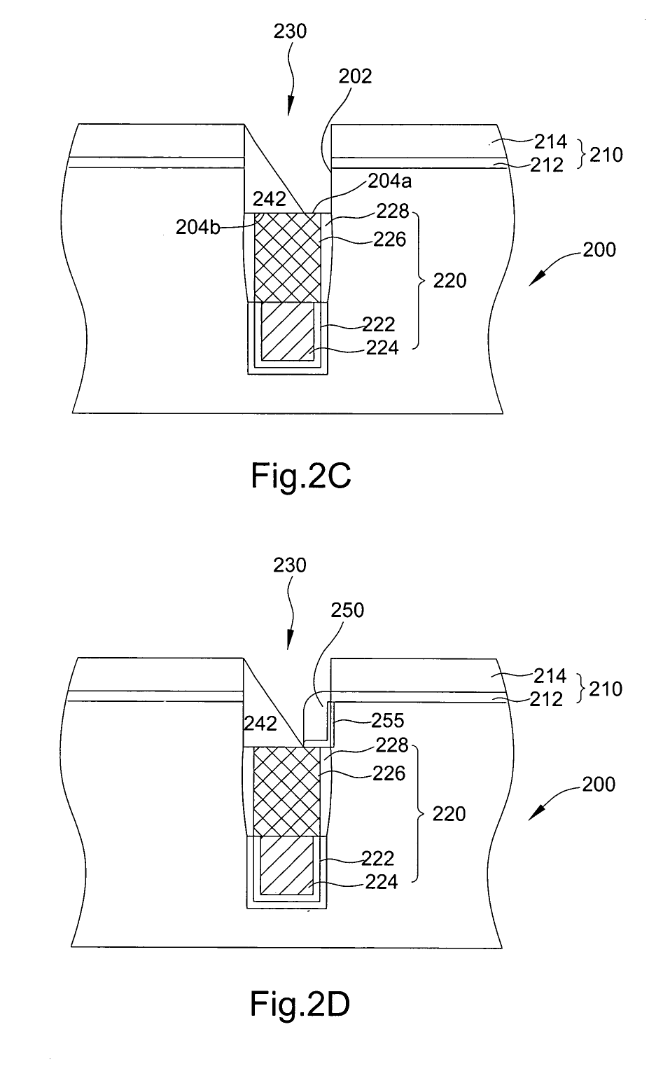

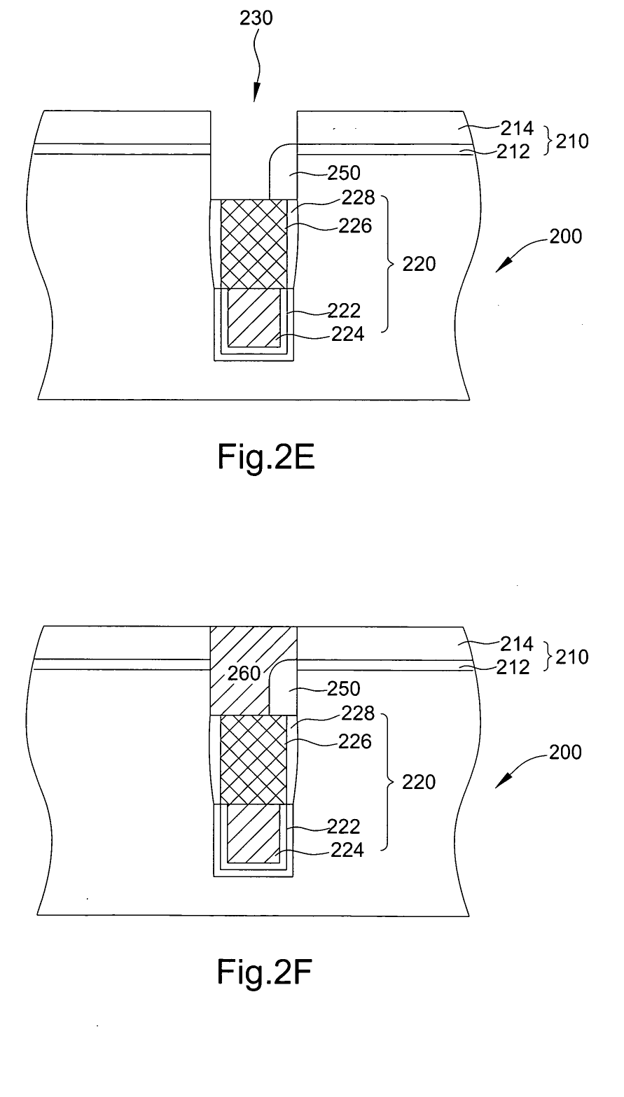

The present invention discloses a method of forming a single sided conductor, which utilizes a tilted mask layer and a selective deposition technique to form the single sided conductor having sub-lithographic feature size and excellent profile. FIGS. 1 and 2 illustrate preferred embodiments of the present invention.

Referring to FIGS. 1A to 1D, in one embodiment, the present invention provides a method of forming a single sided conductor. The method includes providing a substrate 100, which has an opening 110. The opening 110 exposes a sidewall 102 and an opening base surface 104. As shown in FIG. 1B, a tilted mask layer 120 is formed in the opening 110. The tilted mask layer 120 exposes the sidewall 102 and a portion 104a of the opening base surface 104 and covers the other portion 104b of the opening base 104. The step of forming the tilted mask layer 120 includes forming a layer of photoresist, which partially fills the opening 110. Then, the substrate 100 is titled to reflow the photoresist layer, so that the tilted mask layer 120 is formed in the opening 110, as shown in FIG. 1B.

As shown in FIG. 1C, a dielectric layer 130 is formed on the exposed sidewall 102 and the exposed portion 104a of the opening base surface 104. The dielectric layer can be formed by selective deposition technique, such as liquid phase deposition, so that the dielectric layer 130 is selectively deposited on predetermined surfaces, such as the exposed sidewall 102 and the exposed portion 104a of the opening base surface 104, and not deposited on the tilted mask layer 120. Furthermore, by selecting appropriate surface material of the substrate 100, the dielectric layer 130 is selectively not deposited on the surface of the substrate 100. Then, the tilted mask layer 120 is stripped, and a conductive layer 140 is formed, as shown in FIG. 1D. Therefore, the single sided conductor of sub-lithographic feature size is formed without implementing extra lithography processes.

The present invention can be applied to the manufacture of any semiconductor device in need of single sided conductor, for example, a single sided buried strap of a capacitor or a vertical transistor, but not limited thereto. Therefore, another embodiment is described hereinafter in detail.

Referring to FIG. 2A, in a second embodiment, the present invention provides a method of forming a semiconductor device having a single sided conductor, such as a trench capacitor. The method includes providing a semiconductor substrate 200, such as a silicon wafer or a silicon-containing substrate. The semiconductor substrate 200 has a pad dielectric layer 210 formed thereon, a storage node 220 formed therein, and an opening etched therein 230. The opening 230 exposes a sidewall 202, and a surface 204 of the storage node 220. The pad dielectric layer 210 includes a pad oxide layer 212 and a pad nitride layer 214, which can be formed by conventional deposition processes and act as a hard mask in subsequent processes. The storage node 220 of the capacitor is formed in the semiconductor substrate 200 by conventional processes, such as lithography, etch, deposition, oxidation, etc. The storage node 220 of the capacitor includes a capacitor dielectric layer 222, such as oxide/nitride layer, a capacitor conductor 224, such as a polysilicon layer, and other layers formed thereon, such as a conductive plug 226 and a collar dielectric layer 228. The layers of storage node 220 of the capacitor can be formed by conventional lithography, etch, deposition, oxidation, etc, and not elaborated hereinafter.

A layer of photoresist 240 is coated on the pad dielectric layer 210. A portion of the photoresist is removed, so that the opening 230 is partially filled with the photoresist layer 240, as shown in FIG. 2B. In other words, the photoresist layer is firstly coated over the semiconductor substrate 200 and fills the opening 230. The, the photoresist on the pad dielectric layer 210 and a portion of the photoresist in the opening 230 are removed, so that the photoresist layer 240 having a predetermined thickness is remained in the opening 230. Then, the semiconductor substrate 200 is tilted to reflow the photoresist layer 240 to form a tilted photoresist layer 242 in the opening 230. The tilted photoresist layer 242 exposes the sidewall 202 and a portion 204a of the surface 204 of the storage node 220, as shown in FIG. 2C. It is noted that by adjusting the tilt angle of the semiconductor substrate 200 and the thickness of the photoresist layer 240 remained in the opening 230 can control the size (lateral width) of the single sided conductor. For example, if the thickness of the photoresist layer 240 is about half-filled the opening 230, and the semiconductor substrate 200 is tilted about 45 degree, the photoresist is flowed toward the lower sidewall of the opening 230 and exposes about half the surface 204 of the storage node 220. That is, the exposed portion 204a is about equal to the covered portion 204b. Furthermore, if the tilted angle is less than 45 degree, the exposed portion 204a is smaller then the covered portion 204b. It is noted that when adjusting the tilt angle of the semiconductor substrate and the thickness of the photoresist layer, the thickness of photoresist layer 240 is preferably a thickness that the photoresist can cover the predetermined surface or expose the predetermined surface in a predetermined tilt angle, but not reflow out of the opening 230. Therefore, problems induced due to the overflow of photoresist can be eliminated.

Moreover, during the reflow of the photoresist layer 240, the semiconductor substrate 200 is preferably heated to improve the reflow process of the photoresist layer 240. The semiconductor substrate 200 is preferably heated to a temperature about 100 to 150° C. for about 100-150 seconds. It is noted that the temperature and the time of heating the semiconductor substrate 200 can vary with the selection of the photoresist so as to form the tilted photoresist layer in a predetermined profile. Moreover, after the photoresist layer 240 is reflowed, the photoresist is hardened by ultraviolet. In this step, the solvent in the photoresist is removed and the profile of the titled photoresist layer 242 is enhanced.

As shown in FIG. 2D, a dielectric layer 250 is formed on the exposed sidewall 202 and the exposed surface 204a. The dielectric layer 250 can be a selectively deposited dielectric layer, such as a liquid phase deposition formed oxide layer, which is selectively deposited on surfaces of a predetermined material. Therefore, the dielectric layer 250 can be controlled to deposit on the exposed sidewall 202 and the exposed surface 204a of the storage node 220, but not on the tilted photoresist layer 242. For example, before the dielectric layer 250 is formed, a native oxide layer 255 is grown on the exposed sidewall 202 and the exposed surface 204a of the storage node 220. Therefore, the oxide layer formed by liquid phase deposition is selectively deposited on the native oxide layer 255. It is noted that before the dielectric layer 250 is formed, an ozone ashing step is performed to remove the residual photoresist on the exposed sidewall 202 and the exposed surface 204a of the storage node 220. A portion of the tilted photoresist layer 242 may be removed in the ozone ashing step to further adjust the profile of the exposed portion 204a of the storage node 220.

Referring to FIG. 2E, the tilted photoresist layer 242 is removed to expose the covered portion 204b of the storage node 220. As shown in FIG. 2F, a conductive layer 260, such as a polysilicon layer, is formed over the semiconductor substrate 200 upon the exposed surface 204b of the storage node 220 and electrically coupled to the conductive plug 226.

According to different design needs, by adjusting the tilt angle of the substrate and the thickness of the photoresist in the opening, the feature size of the single sided conductor of the present invention can be controlled. Moreover, the single sided conductor can be a sub-lithographic feature formed without implementing extra lithography processes.

Although specific embodiments have been illustrated and described, it will be obvious to those skilled in the art that various modifications may be made without departing from what is intended to be limited solely by the appended claims.

1. A method of forming a single sided conductor, comprising:
providing a substrate having an opening, said opening exposing a sidewall and an opening base surface;
forming a tilted mask layer in said opening, said tilted mask layer exposing said sidewall and a portion of said opening base surface; and
forming a dielectric layer on said exposed sidewall and said exposed opening base surface.

2. The method of claim 1, wherein said step of forming said tilted mask layer comprises:
coating a layer of photoresist over said substrate;
removing a portion of said photoresist such that said opening is partially filled with said photoresist; and
tilting said substrate to reflow said photoresist layer to form said tilted mask layer in said opening.

3. The method of claim 2, wherein said substrate is heated during the reflow of said photoresist layer.

4. The method of claim 3, wherein said substrate is heated to a temperature about 100 to 150° C. for about 100-150 seconds.

5. The method of claim 2, further comprising a step of hardening said photoresist layer by ultraviolet after said photoresist layer is reflowed.

6. The method of claim 1, further comprising an ozone ashing step before said dielectric layer is formed.

7. The method of claim 1, wherein a native oxide layer is grown on sad exposed sidewall and said exposed opening base surface before said dielectric layer is formed.

8. The method of claim 7, wherein said dielectric layer is an oxide layer formed by liquid phase deposition.

9. The method of claim 1, further comprising a step of stripping said tilted mask layer.

10. The method of claim 9, wherein a conductive layer is formed over said substrate after said tilted mask layer is stripped.

11. A method of forming a semiconductor device having a single sided conductor, comprising:
providing a semiconductor substrate having a pad dielectric layer thereon, a storage node therein, and an opening etched therein, said opening exposing a sidewall and a surface of said storage node;
coating a layer of photoresist on said pad dielectric layer;
removing a portion of said photoresist such that said opening is partially filled with said photoresist;
tilting said semiconductor substrate to reflow said photoresist layer to form a tilted photoresist layer in said opening, said tilted photoresist layer exposing said sidewall and a portion of said surface of said storage node;
forming a dielectric layer on said exposed sidewall and said exposed surface;
removing said tilted photoresist; and
forming a conductive layer over said semiconductor substrate.

12. The method of claim 11, wherein said semiconductor substrate is heated during the reflow of said photoresist layer.

13. The method of claim 12, wherein said semiconductor substrate is heated to a temperature about 100 to 150° C. for about 100-150 seconds.

14. The method of claim 11, further comprising a step of hardening said photoresist layer by ultraviolet after said photoresist layer is reflowed.

15. The method of claim 11, further comprising a step of ozone ashing before said dielectric layer is formed.

16. The method of claim 11, wherein a native oxide layer is grown on sad exposed sidewall and said exposed surface of said storage node before said dielectric layer is formed.

17. The method of claim 16, wherein said dielectric layer is an oxide layer formed by liquid phase deposition.
